(19) United States
(12) Patent Application Publication
(10) Pub. No.: US 2005/0161790 A1
(43) Pub. Date: Jul. 28, 2005

(54) Stacked IC

(76) Inventor: Cheng-Hsun Tsai, Taipei (TW)

Correspondence Address: MADSON & METCALF;GATEWAY TOWER WEST, SUITE 900, 15 WEST SOUTH TEMPLE, SALT LAKE CITY, UT, 84101, US

(21) Appl. No.: 10/763,139

(22) Filed: Jan. 22, 2004

(51) Int. Cl. H01L 23/02

(52) U.S. Cl. 257/685; 257/686

(57) ABSTRACT

A stacked IC includes a first IC package unit, a second IC package unit and an interface layer. The first IC package unit includes an IC chip, an encapsulant resin and a plurality of lead wires. The IC chip is encapsulated by the encapsulant resin. Each of the lead wires includes a first end connected to the IC chip and encapsulated by the encapsulant resin and a second end extending outside the encapsulant resin. The interface layer has a first side connected to soldering portions of the lead wires of the first IC package unit via a plurality of solder balls and a second side connected to the second IC package unit.

### FIELD OF THE INVENTION

The present invention relates to a stacked IC, and more particularly to a stacked IC with a plurality of package units in a stack form.

### BACKGROUND OF THE INVENTION

With the rapid progress of semiconductor industries, the integrated circuits (ICs) used in electronic devices are developed toward minimization, high operating speed and increasing integration level. In a computer system or similar electronic products, CPU determines system performance, and the capacity and the operating speeds of the memory chips are important factors that affect data processing efficiency. Take a memory chip for example. Nowadays, for complying with a requirement of miniaturization, the memory chip is designed to have a high storage capacity with a reduced size. For a purpose of reducing cost and size, a so-called stacking method is widely used to interconnect multiple memory chips in a stack form so as to form a memory module, i.e. a stacked IC.

Referring to FIG. 1, a conventional stacked IC is shown. The stacked IC 1 comprises a first IC package unit 11 and a second IC package unit 12 in a stack form. The first IC package unit 11 and the second IC package unit 12 are provided on the bottom and the top of the stacked IC, respectively. Each of the IC package units 111 and 12 comprises an IC chip, a lead frame and a plurality of lead wires. In order to make electrical connection between these two IC package units 11 and 12, the lead wires 121 of the second IC package unit 12 should be bent inward to be in contact with the lead wires 111 of the first IC package unit 11 and then soldered thereon. Although the manner for fabricating this stacked IC 1 is cost effective, the internal structure of the second IC package unit 12 may be damaged during the operation of bending the lead wires 121. In addition, such manner is time-consuming.

Referring to FIG. 2, another conventional stacked IC is shown. The stacked IC 2 comprises a first IC package unit 21, a second IC package unit 22 and an interface layer 23 sandwiched between the IC package units 21 and 22. Each of the IC package units 21 and 22 comprises an IC chip, a lead frame and a plurality of lead wires. The interface layer 23 has a plurality of bent pins 231 extending from the bilateral edges thereof. In order to make electrical connection between these two IC package units 21 and 22, the lead wires 221 of the second IC package unit 22 is firstly soldered onto the interface layer 23. The bent pins 231 of the interface layer 23 are then soldered onto the lead wires 211 of the first IC package unit 21 so as to form the stacked IC 2. The manner for fabricating this stacked IC 2 is more complicated because the pins 231 of the interface layer 23 need to be bent in advance and the soldering procedure should be done manually.

Referring to FIG. 3, another conventional stacked IC is shown. The stacked IC 3 comprises a first IC package unit 31 and a second package unit 32. Each of the IC package units 31 and 32 comprises a chip, a lead frame and a plurality of lead wires. Each terminal of the lead wires 311 and 321 for the respective IC package units 31 and 32 is connected to a conductor 33, 34. The connection of the conductors 33 and 34 performs the electrical connection between these two IC package units 31 and 32. The manner for fabricating this stacked IC 3 uses no interface layer. However, this manner is more time-consuming and costly because two stages are required to make electrical connection, i.e. (1) the conductors should be coupled to the terminals of the lead wires, and (2) these conductors are further connected with each other.

### SUMMARY OF THE INVENTION

It is an object of the present invention to provide a stacked IC with a plurality of package units in a stack form, in which the stacked IC is easily packaged and cost-effective.

In accordance with a first aspect of the present invention, there is provided a stacked IC. The stacked IC comprises a first IC package unit, a second IC package unit and an interface layer. The first IC package unit comprises an IC chip, an encapsulant resin and a plurality of lead wires. The IC chip is encapsulated by the encapsulant resin. Each of the lead wires comprises a first end connected to the IC chip and encapsulated by the encapsulant resin and a second end extending outside the encapsulant resin. The second end extending outside the encapsulant resin comprises first and second soldering portions. The second IC package unit has the same structure as the first IC package unit. The interface layer is sandwiched between the first IC package unit and the second IC package unit, and has first and second sides with a plurality of soldering pads. Each first soldering portion of the first IC package unit is connected to corresponding soldering pad on the first side of the interface layer via a solder ball. Each second soldering portion of the second IC package unit is connected to corresponding soldering pad on the second side of the interface layer via a soldering material other than the solder ball, thereby achieving electrical connection between the first IC package unit and the second IC package unit.

In an embodiment, the first and the second soldering portions are in the vicinity of and distant from the encapsulant resin, respectively.

In an embodiment, each of the first and the second soldering portions is substantially parallel to the interface layer.

In an embodiment, the interface layer is made of a hard dielectric material.

In an embodiment, the interface layer is made of a soft dielectric material.

In an embodiment, the IC chip for each of the first IC package unit and the second IC package unit is selected from a group consisting of a memory chip, an application specific integrated circuit (ASIC) chip and a driving integrated circuit chip.

In an embodiment, each of the first IC package unit and the second IC package unit is a thin small outline package (TSOP).

In an embodiment, each of the first IC package unit and the second IC package unit is a quad flat pack (QFP).

In accordance with a second aspect of the present invention, there is provided a stacked IC. The stacked IC comprises a first IC package unit, a second IC package unit and an interface layer. The first IC package unit comprises an IC chip, an encapsulant resin and a plurality of lead wires. The IC chip is encapsulated by the encapsulant resin. Each of the lead wires comprises a first end connected to the IC chip and encapsulated by the encapsulant resin and a second end extending outside the encapsulant resin. The interface layer has a first side connected to soldering portions of the lead wires of the first IC package unit via a plurality of solder balls and a second side connected to the second IC package unit.

In an embodiment, the first IC package unit is selected from a group consisting of a thin small outline package (TSOP), a quad flat pack (QFP), a small outline package (SOP), a pin grid array (PGA), and a small outline package J-leaded package (SOJ).

In an embodiment, the second IC package unit is selected from a group consisting of a thin small outline package (TSOP), a quad flat pack (QFP), a ball grid array (BGA), a small outline package (SOP), a pin grid array (PGA), and small outline package J-leaded package (SOJ).

In accordance with a third aspect of the present invention, there is provided a stacked IC. The stacked IC comprises a first IC package unit, a second IC package unit and an interface layer. The first IC package unit is selected from a group consisting of a thin small outline package (TSOP), a quad flat pack (QFP), a small outline package (SOP), a pin grid array (PGA), and a small outline package J-leaded package (SOJ). The second IC package unit is selected from a group consisting of a thin small outline package (TSOP), a quad flat pack (QFP), a ball grid array (BGA), a small outline package (SOP), a pin grid array (PGA), and small outline package J-leaded package (SOJ). The interface layer has a first side connected to the first IC package unit via a plurality of solder balls and a second side connected to the second IC package unit.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating a conventional stacked IC packaged in a stack form;

FIG. 2 is a schematic view illustrating another conventional stacked IC packaged in a stack form;

FIG. 3 is a schematic view illustrating another conventional stacked IC packaged in a stack form;

FIG. 4(a) is a schematic front view illustrating a stacked IC packaged in a stack form according to a first embodiment of the present invention;

FIG. 4(b) is a schematic side view of FIG. 4(a);

FIG. 5 is a schematic view illustrating an IC module with a plurality of stacked ICs; and

FIG. 6 is a schematic front view illustrating an IC package unit according to another embodiment of the present invention.

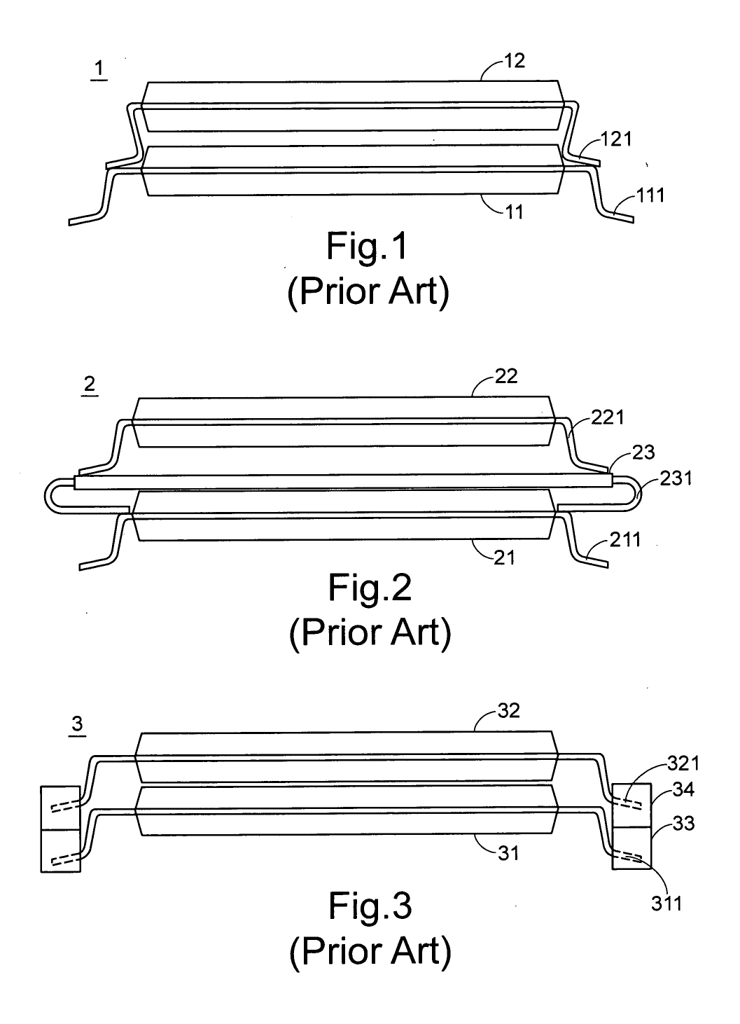

### DETAILED DESCRIPTION OF THE PREFERRED EMBODIMENT

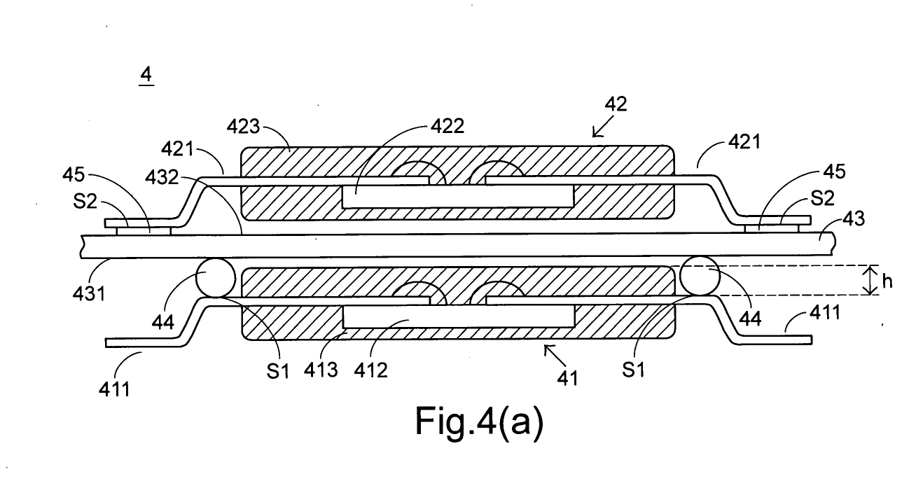

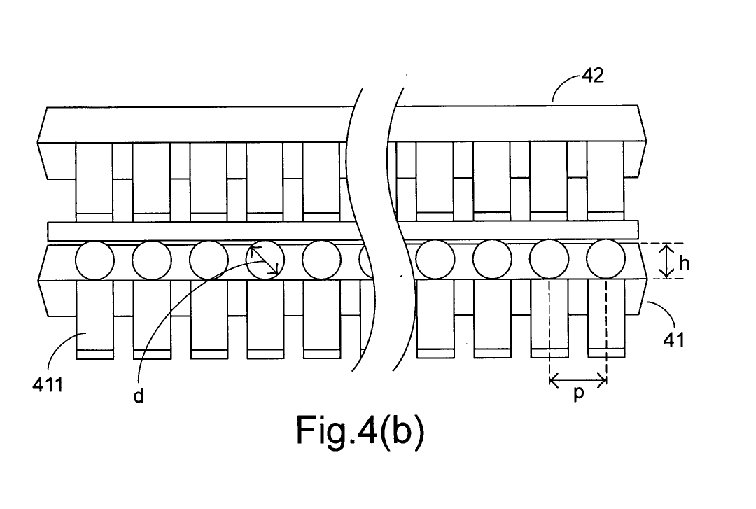

Referring to FIGS. 4(a) and 4(b), a stacked IC according to a first embodiment of the present invention is shown. The stacked IC 4 comprises a first IC package unit 41, a second IC package unit 42 and an interface layer 43. The first IC package unit 41 and the second IC package unit 42 have the same structure and are provided on the bottom and the top of the stacked IC, respectively. The interface layer 43 is sandwiched between the first IC package unit 41 and the second IC package unit 42. The interface layer 43 has a first surface 431 and a second surface 432 connected to the first IC package unit 41 and the second IC package unit 42, respectively. The interface layer 43 can be made of hard or soft dielectric material.

The first IC package unit 41 comprises a plurality of first lead wires 411, a first IC chip 412 and a first encapsulant resin 413. Each first lead wire 411 has one end electrically connected to the first IC chip 412 and the other end exposed outside the first encapsulant resin 413. As shown in FIG. 4(a), the lead wire 411 exposed outside the first encapsulant resin 413 has been previously bent twice so as to form a first soldering portion S1 in the vicinity of the first encapsulant resin 413. Likewise, the second IC package unit 42 comprises a plurality of second lead wires 421, a second IC chip 422 and a second encapsulant resin 423. Each second lead wire 421 has one end electrically connected to the second IC chip 422 and the other end exposed outside the second encapsulant resin 423. Likewise, the lead wire 421 exposed outside the second encapsulant resin 423 has been previously bent twice so as to form a second soldering portion S2 distant from the second encapsulant resin 423. For a purpose of enhancing adhesion, the first soldering portion S1 and the second soldering portion S2 are substantially parallel to the interface layer 43.

The first IC package unit 41 can be a thin small outline package (TSOP), a quad flat pack (QFP), a small outline package (SOP), a pin grid array (PGA), or a small outline package. J-leaded package (SOJ). Preferably, the first IC package unit 41 is selected from a thin small outline package (TSOP) or a quad flat pack (QFP). The diameter (d) of the solder ball 44 is varied according to the type of the first IC package unit 41, the pitch (p) between two adjacent first lead wires 411 and the height (h) from the first soldering portion S1 of the lead wires 411 to the top surface of the encapsulant resin 413. Experimentally, it has been found that
h+0.3 mm≦d≦p−0.2 mm

Take a TSOP II-54 unit selected as the first IC package unit 41 for example. The height h is about 0.12 mm, and the pitch p is about 0.8 mm. The diameter d of the solder ball 44 is in the range of from 0.42 to 0.6 mm, for example 0.45 mm.

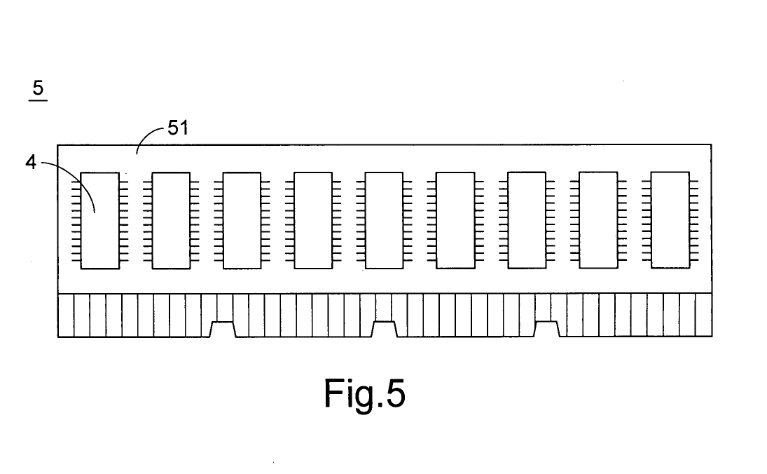

Referring to FIG. 5, an IC module 5 comprising a circuit board 51 and a plurality of stacked ICs 4 is shown. The stacked ICs 4 are arranged on the top and the bottom surfaces of the circuit board 51. The structure of respective stacked IC 4 is similar to that of FIG. 4(a), which is not intended to be described redundantly herein.

Since the solder balls can be readily and accurately placed and aligned, the stacked IC of the present invention will be automatically fabricated so as to achieve high performance. Therefore, the process for fabricating the stacked IC of the present invention is more cost-effective, simpler and has higher capacity when compared with the prior art product.

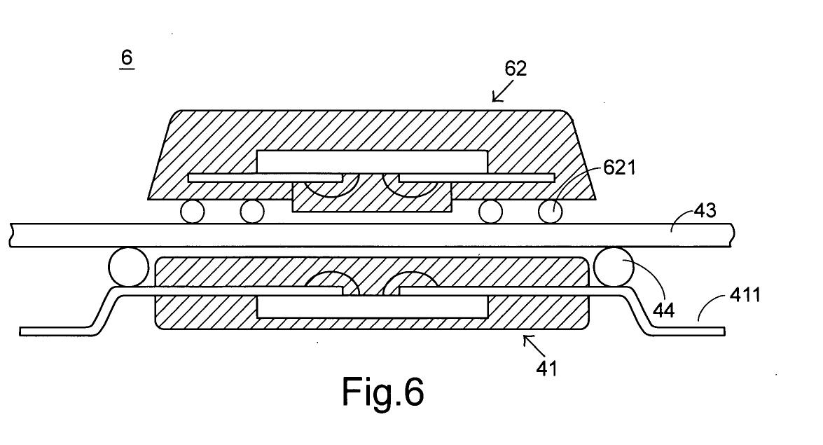

Referring to FIG. 6, a schematic view of a stacked IC 6 according to another embodiment of the present invention is shown. This stacked IC is similar to that of FIG. 4, except that the second IC package unit 42 arranged on the top is replaced by a ball grid array (BGA) unit 62. The solder ball 621 of the BGA package unit 62 is bonded to the corresponding soldering pads on the top of the interface layer 43 so as to make electrical connection of the first IC package unit 41 and the BGA package unit 62.

In addition to the configuration of the thin small outline package (TSOP) or the quad flat pack (QFP) shown in FIG. 4 or the ball grid array (BGA) shown in FIG. 6, the second IC package unit 42 can be selected from a small outline package (SOP), a pin grid array (PGA) or a small outline package J-leaded package (SOJ).

The present invention is illustrated by referring to a stacked IC with two stacked memory chips such as DRAM, DDR DRAM, RAMBUS DRAM, FLASH or SRAM. Nevertheless, the present invention can be applied to application specific integrated circuit (ASIC) or the driving integrated circuit of the liquid crystal display device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A stacked IC comprising:
a first IC package unit comprising an IC chip, an encapsulant resin and a plurality of lead wires, said IC chip being encapsulated by said encapsulant resin, wherein each of said lead wires comprises a first end connected to said IC chip and encapsulated by said encapsulant resin and a second end extending outside said encapsulant resin, wherein said second end extending outside said encapsulant resin comprises first and second soldering portions;
a second IC package unit having the same structure as said first IC package unit; and
an interface layer sandwiched between said first IC package unit and said second IC package unit, and having first and second sides with a plurality of soldering pads, wherein each first soldering portion of said first IC package unit is connected to corresponding soldering pad on said first side of said interface layer via a solder ball, and each second soldering portion of said second IC package unit is connected to corresponding soldering pad on said second side of said interface layer via a soldering material other than said solder ball, thereby achieving electrical connection between said first IC package unit and said second IC package unit.

2. The stacked IC according to claim 1 wherein said first and said second soldering portions are in the vicinity of and distant from said encapsulant resin, respectively.

3. The stacked IC according to claim 1 wherein each of said first and said second soldering portions is substantially parallel to said interface layer.

4. The stacked IC according to claim 1 wherein said interface layer is made of a hard dielectric material.

5. The stacked IC according to claim 1 wherein said interface layer is made of a soft dielectric material.

6. The stacked IC according to claim 1 wherein said IC chip for each of said first IC package unit and said second IC package unit is selected from a group consisting of a memory chip, an application specific integrated circuit (ASIC) chip and a driving integrated circuit chip.

7. The stacked IC according to claim 1 wherein each of said first IC package unit and said second IC package unit is a thin small outline package (TSOP).

8. The stacked IC according to claim 1 wherein each of said first IC package unit and said second IC package unit is a quad flat pack (QFP).

9. A stacked IC comprising:
a first IC package unit comprising an IC chip, an encapsulant resin and a plurality of lead wires, said IC chip being encapsulated by said encapsulant resin, wherein each of said lead wires comprises a first end connected to said IC chip and encapsulated by said encapsulant resin and a second end extending outside said encapsulant resin;
a second IC package unit; and
an interface layer having a first side connected to soldering portions of said lead wires of said first IC package unit via a plurality of solder balls and a second side connected to said second IC package unit.

10. The stacked IC according to claim 9 wherein said interface layer is made of a hard dielectric material.

11. The stacked IC according to claim 9 wherein said interface layer is made of a soft dielectric material.

12. The stacked IC according to claim 9 wherein said IC chip is selected from a group consisting of a memory chip, an application specific integrated circuit (ASIC) chip and a driving integrated circuit chip.

13. The stacked IC according to claim 9 wherein said first IC package unit is selected from a group consisting of a thin small outline package (TSOP), a quad flat pack (QFP), a small outline package (SOP), a pin grid array (PGA), and a small outline package J-leaded package (SOJ).

14. The stacked IC according to claim 9 wherein said second IC package unit is selected from a group consisting of a thin small outline package (TSOP), a quad flat pack (QFP), a ball grid array (BGA), a small outline package (SOP), a pin grid array (PGA), and small outline package J-leaded package (SOJ).

15. A stacked IC comprising:
a first IC package unit selected from a group consisting of a thin small outline package (TSOP), a quad flat pack (QFP), a small outline package (SOP), a pin grid array (PGA), and a small outline package J-leaded package (SOJ);
a second IC package unit selected from a group consisting of a thin small outline package (TSOP), a quad flat pack (QFP), a ball grid array (BGA), a small outline package (SOP), a pin grid array (PGA), and a small outline package J-leaded package (SOJ); and
an interface layer having a first side connected to said first IC package unit via a plurality of solder balls and a second side connected to said second IC package unit.

16. The stacked IC according to claim 15 wherein said interface layer is made of a hard dielectric material.

17. The stacked IC according to claim 15 wherein said interface layer is made of a soft dielectric material.

18. The stacked IC according to claim 15 wherein said IC chip is selected from a group consisting of a memory chip, an application specific integrated circuit (ASIC) chip and a driving integrated circuit chip.
